(19) United States
(12) Patent Application Publication
(10) Pub. No.: US 2025/0238581 A1
(43) Pub. Date: Jul. 24, 2025

(54) PHYSICS-INFORMED THREE-DIMENSIONAL MOTION GENERATION

(71) Applicant: NEC Laboratories America, Inc., Princeton, NJ (US)

(72) Inventors: Honglu Zhou, Highland Park, NJ (US); Renqiang Min, Princeton, NJ (US); Kai Li, Plainsboro, NJ (US); Jianke Yang, Plainsboro, NJ (US)

(21) Appl. No.: 19/018,690

(22) Filed: Jan. 13, 2025

Related U.S. Application Data
(60) Provisional application No. 63/622,125, filed on Jan. 18, 2024.

(51) Int. Cl. G06F 30/27; G06T 17/00

(52) U.S. Cl. CPC G06F 30/27; G06T 17/00

(57) ABSTRACT

A device may convert a motion dataset to a compatible representation for use in a physics engine, wherein the physics engine includes a physics simulator and inverse dynamics network. The device may further downsample the motion dataset to obtain keyframes for motion generation and forming a downsampled motion dataset. The device may further execute a deep generative model based on the downsampled motion dataset to generate a first generated motion. The device may further execute the physics engine by feeding pairs of consecutive keyframes into the physics simulator and the inverse dynamics network to generate a second generated motion. The device may further combine the first generated motion and the second generated motion to form a combined generated motion, wherein the combined generated motion is generated by executing the physics engine with the first generated motion. The device may further generate a simulated motion video from the combined generated motion.

### RELATED APPLICATION INFORMATION

This application claims priority to 63/622,125, filed on Jan. 18, 2024, incorporated herein by reference in its entirety.

### BACKGROUND

### Technical Field

The present invention relates to imitating motion and more particularly realistic motion generation that abides by the laws of physics.

### Description of the Related Art

In the field of computer vision and graphics, the generation of realistic motions is pivotal for applications including animation, sports analysis, and biomechanics. The generation of this motion is flawed, however. Deep generative models often generate motions that violate real-world physical laws (including floating effects, penetration errors, and sliding). These issues stem from the fact that deep generative models are proficient in data driven learning but lack an inherent understanding of physical principles governing actual motion.

Physics engines, unlike deep generative models, are grounded in well-established laws of motion and dynamics but have different limitations. Physics-based models often have “reality gaps” due to the simplifications and assumptions in any simulation. For instance, physics engines may overlook more complex phenomena such as air resistance, subtle muscle dynamics, or the intricate effects of varying material properties. Also, physics engines typically proceed in an autoregressive fashion, which is markedly less efficient than deep generative models. The sequential generation process of a physics simulator is prone to cumulative errors, and inaccuracies in early frames can propagate through the simulation, leading to larger deviations over time. Also, physics engines incur high computational costs to avoid cumulative errors.

### SUMMARY

In some aspects, the techniques described herein relate to a method, including converting a motion dataset to a compatible representation for use in a physics engine, wherein the physics engine includes a physics simulator and inverse dynamics network, downsampling the motion dataset to obtain keyframes for motion generation and forming a downsampled motion dataset, executing a deep generative model based on the downsampled motion dataset to generate a first generated motion, executing the physics engine by feeding pairs of consecutive keyframes into the physics simulator and the inverse dynamics network to generate a second generated motion, combining the first generated motion and the second generated motion to form a combined generated motion, wherein the combined generated motion is generated by executing the physics engine with the first generated motion, and generating a simulated motion video from the combined generated motion.

In some aspects, the techniques described herein relate to a system, including a hardware processor and a memory that stores a computer program which, when executed by the hardware processor, causes the hardware processor to convert a motion dataset to a compatible representation for use in a physics engine, wherein the physics engine includes a physics simulator and inverse dynamics network, downsample the motion dataset to obtain keyframes for motion generation and forming a downsampled motion dataset; execute a deep generative model based on the downsampled motion dataset to generate a first generated motion, execute the physics engine by feeding pairs of consecutive keyframes into the physics simulator and the inverse dynamics network to generate a second generated motion, combine the first generated motion and the second generated motion to form a combined generated motion, wherein the combined generated motion is generated by executing the physics engine with the first generated motion, and generate a simulated motion video from the combined generated motion.

In some aspects, the techniques described herein relate to a computer program product including a non-transitory computer-readable storage medium containing computer program code, the computer program code when executed by one or more processors causes the one or more processors to perform operations, the computer program code including instructions to convert a motion dataset to a compatible representation, for use in a physics engine, wherein the physics engine includes a physics simulator and inverse dynamics network, downsample the motion dataset to obtain keyframes for motion generation and forming a downsampled motion dataset, execute a deep generative model based on the downsampled motion dataset to generate a first generated motion, execute the physics engine by feeding pairs of consecutive keyframes into the physics simulator and the inverse dynamics network to generate a second generated motion, combine the first generated motion and the second generated motion to form a combined generated motion, wherein the combined generated motion is generated by executing the physics engine with the first generated motion, and generate a simulated motion video from the combined generated motion.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a high-level method for generating training motion incorporating a deep generative model and a physics engine, in accordance with an embodiment of the present invention;

FIG. 2 is a high-level method for generating motion incorporating a deep generative model and a physics engine, in accordance with an embodiment of the present invention;

FIG. 3 is a flow diagram demonstrating the process of downsampling and interpolating motion generation, in accordance with an embodiment of the present invention;

FIG. 4 is pseudocode of an algorithm of a method for downsampling and interpolating motion generation as demonstrated in FIG. 2, in accordance with an embodiment of the present invention;

FIG. 5 is pseudocode of an algorithm of a method for smoothing generated motion, in accordance with an embodiment of the present invention; and

FIG. 6 is a block diagram showing an exemplary processing system, in accordance with an embodiment of the present invention.

### DETAILED DESCRIPTION OF PREFERRED EMBODIMENTS

In accordance with embodiments of the present invention, systems and methods are provided for generated motion which simulates the motion of an object in a given space.

In embodiments of the present invention, a deep generative model is incorporated with a physics engine. The combination of a deep generative model and physics engine applies the advantages of each while minimizing detrimental effects. The deep generative engine generates motion while the physics engine ensures the generation abides by the laws of physics.

Deep generative models can efficiently produce motion animations but since motion can be unpredictable and diverse on the aggregate, these deep generative models may appear unrealistic or violate the laws of physics. Physics engines accurately depict the physical world and can aid in predicting motion. Physics engines can do this because motion at a granular level is nearly deterministic, but physics engines are computationally expensive. The combined deep generative model and physics engine can generate motion advantageously. By producing downsampled keyframes of the entire motion, the physics engine can consider physical limitations while the deep generative model completes the remainder of the motion animation.

Keyframes are frames selected for features the keyframes include. For example, a keyframe can be selected to demonstrate a particular structure (e.g., a human limb or other portion of a structure which motion is generated for that has at least one joint) configuration. For example, a keyframe can be selected to demonstrate a complex human body pose.

A pose is the form of a structure at a given time, even if only intermediary and the pose may or may not be able to be sustained because the pose is a transitory stage while going to another pose. For example, poses (and therefore keyframes) can include the positioning of a human body while going into unique or difficult yoga poses, where the pose cannot be maintained and is only achieved by attempting to get into another pose that is maintainable. Poses can also capture visualizations of the maximal extent joints extend in various directions in all three dimensions.

While a deep generative model is capable of producing high-quality, diverse, and efficient motion generation, the deep generative model is data intensive and is unaware of the laws of physics (and therefore can violate the law of physics). A physics simulator obeys the laws of physics and can aid in generating realistic motion.

Combining the deep generative model and physics simulator takes advantage of the different characteristics of motion at varying temporal scales. For example, at larger scales, movements are more stochastic and diverse, which can be effectively captured by data-driven models, like the deep generative model. In contrast, at smaller scales, motion tends to be more deterministic and governed by the laws of physics, making the physics simulator more suitable for simulation through physics equations, like incorporated in the physics engine.

For example, humans can choose arbitrary routes between a starting point and a destination. However, considering the movement within a small interval, e.g., one step, motion will follow a more deterministic pattern, influenced more by the laws of physics of motion rather than human free-will. Thus, at a high level, the deep generative model is preferred to generate the coarse trajectory of human motion. Then, given two adjacent frames in the generated motion, the physics engine is preferred to interpolate the motion in between frames to produce the full trajectory.

The advantages of combining the deep generative model and physics engine are numerous, including (1) downsampling reduces temporal dimensionality of the motion sequences and therefore reduces the difficulty of training the deep generative model; (2) allowing the model to have different starting frames to obtain multiple sequences from one original motion sequence sample, which is an implicit data augmentation that improves the generalization ability and robustness to noise of the trained model; (3) minimizing the error propagation and numerical instability issues of the physics engine; and (4) allowing the combined model to produce detailed and physically reasonable motions by incorporating the physics simulator and an inverse dynamics network to interpolate generated motions.

Motion and motion generation can come in many forms including both inanimate objects and living organisms. Present embodiments of the invention are agnostic to any type of motion or any particular deep generative model or physics engine.

A motion dataset is collected. The dataset can include physical concepts of various portions of a structure over a certain amount of time. The dataset can then be parsed such that there are frames depicting the motion at a specific time. The most useful frames can be denoted as keyframes. The dataset can then be downsampled such that only the keyframes remain. Using the downsampled dataset, the keyframes can be sent to a physics engine and deep generative model. The deep generative model can use the downsampled dataset to produce motion. The physics engine which includes an inverse dynamics network and physics simulator can use the downsampled dataset to predict motion that abides by the laws of physics. The inverse dynamics network predicts motion, and the physics simulator verifies that the motion is realistic and abides by the laws of physics. The inverse dynamics network and physics simulator can feed information into one another. Using the deep generative model with the physics engine result, the physics engine can output a complete and physically accurate generated motion dataset.

The generated motion dataset can the be smoothed by repeating the process by starting at different keyframes or selecting the keyframes as slightly offset times. In other words, selecting frames slightly before or after the initial keyframes.

The generated motion can be used in a variety of circumstances. For example, generated motion can be used to train autonomous vehicles. Capturing motion for autonomous vehicle training is a lengthy and costly process. Reducing the amount of time and cost of training autonomous vehicles by simulating much of the motion would be advantageous. New motion can also be generated by inserting keyframes not from the original dataset. This would allow the autonomous vehicle to learn scenarios that it would not otherwise be able to train in a temporally and economically effective manner. Another example may be in healthcare. Generating motion may show doctors how a prosthetic limb would be used and act in the fitting and research and development (R&D) phase. The advantages are similar to those of training an autonomous vehicle. Other examples that generated motion may be used are computational fluid dynamics, computer aided design, computer aided engineering, computer aided machining, and video games.

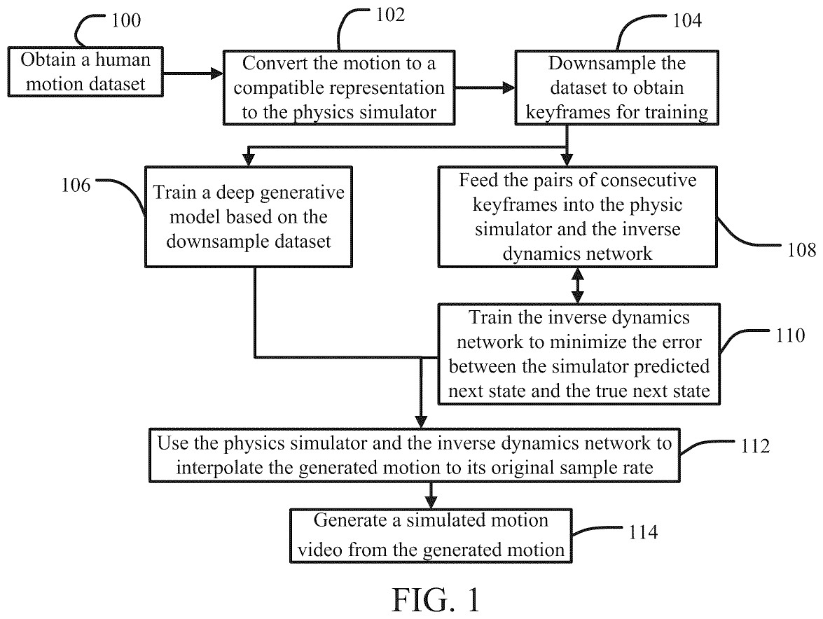

Referring now in detail to the figures in which like numerals represent the same or similar elements and initially to FIG. 1, a high-level method for training motion generation incorporating a deep generative model and a physics engine is illustratively depicted in accordance with one embodiment of the present invention.

Block 100 includes obtaining a motion dataset. In one embodiment this dataset can come from motion capture techniques such as collecting data from sensors. Motion capture can come from sensors such as gyroscopes, accelerometers, active ultrasonic sensors, passive infrared (PIR) sensors, and inertial measurement units (IMUs). In other embodiments, motion capture can come from image and video. The collection of sensor data can build a three-dimensional (3D) model of structures and joints at a given time. Images and videos can be learned through artificial neural networks like a convolutional neural network (CNN) or other methods like a Video Large Language Model (VLLM) to recognize visual information.

Block 102 includes converting the motion from the motion dataset to a compatible representation for the physics engine. This conversion includes assigning generalized and maximal coordinates of the structure joints. The generalized coordinates are the locations the structure joints would be expected to be, and the maximal coordinates are all possible locations the structure could be. For example, contortionists and yogis can reach maximal coordinates that another human likely cannot.

Block 104 includes downsampling the dataset to obtain keyframes for training the deep generative model. Keyframes further include frames of the structure motion at a given time that can include structure in configurations that have advantageous aspects to train on. For example, keyframes may come from a dataset of a person going from a standing position; to walking; to running; to walking; and to a standing position. The keyframes can be exemplary views of the person standing and running. Selecting keyframes that depict the person in transition phases (e.g., walking) would be less advantageous for training because such poses would not demonstrate the maximal coordinates of the structure.

Block 106 includes training a deep generative model based on the downsample dataset. The deep generative model can learn significant features enclosed in the keyframes which differentiate these frames from non-selected frames.

Block 108 includes feeding the pairs of consecutive keyframes into the physics engine which includes a physics simulator and the inverse dynamics network. Block 108 can occur concurrently to block 106. In block 108 the keyframes are used in the physics simulator to ensure the laws of physics are abided by and the inverse dynamics network to predict motion. These are used in tandem to interpolate between consecutive keyframes from the downsampled motions generated by the deep generative model. The physics engine can receive the keyframes and produce a motion sequence of the original length of the captured motion data and the sample rate. The physics simulator is tasked with taking the current state and the next state in downsampled motion keyframes while abiding by the laws of physics.

The inverse dynamics network is concurrently tasked with seamlessly forming a path between the current keyframe to the next keyframe. The inverse dynamics network considers physical concepts including force, torque, acceleration, inertia, moment of inertia, mass, and moments of force. The inverse dynamics network can use physical concepts and kinematics to predict future motion. Other physical concepts are contemplated like jerk, snap, crackle, and pop.

Block 110 includes training the inverse dynamics network to minimize the error between the physics simulator predicted next state and the true next state. Different methodologies to train the inverse dynamics network such as a Recurrent Neural Network (RNN) can be employed.

Block 112 includes using the physics simulator and the inverse dynamics network together to form the physics engine (physics-based interpolator) that includes the details in the downsampled deep generative model output. The training of the inverse dynamics network is decoupled from the training of the deep generative model, but the physics engine can be seamlessly incorporated with the deep generative model to produce detailed and physically reasonable motions at the test/inference time.

Block 114 includes generating a simulated motion video from the generated motion. The simulated motion video can be of any duration, including several seconds to several hours. Post processing operations can be applied to the simulated motion video such as smoothing or simulated audio corresponding to the simulated motion.

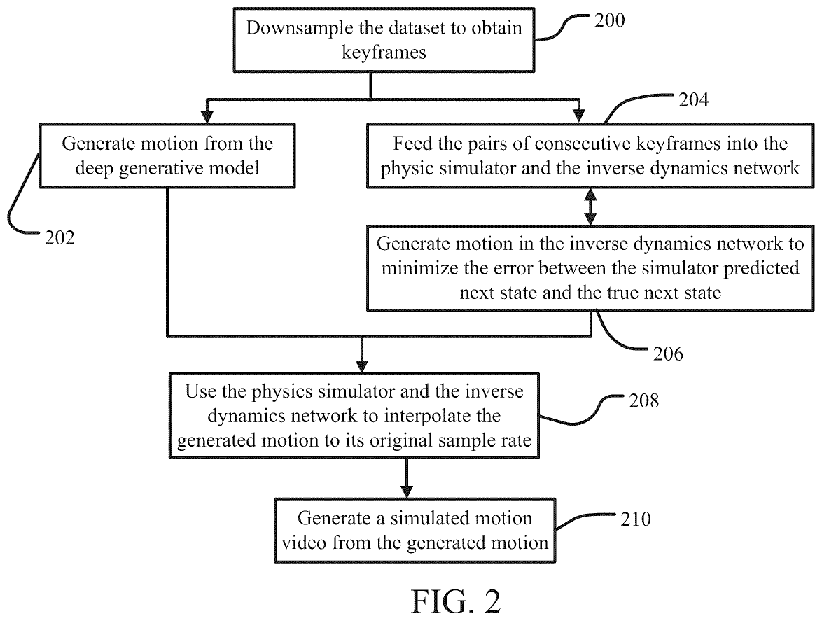

Now referring to FIG. 2, a high-level method for motion generation incorporating a deep generative model and a physics engine is illustratively depicted in accordance with one embodiment of the present invention. While FIG. 1 is for the training stage of motion generation, FIG. 2 is for the inference stage of motion generation. Block 200 includes downsampling the dataset to obtain keyframes for generating motion. The keyframes can be used in both the deep generative model and physics engine. Block 202 includes generating motion in the deep generative model based on the downsample dataset. Block 204 includes feeding pairs of consecutive keyframes into the physics engine. Block 204 can occur concurrently to block 202. In block 204 the keyframes are used in the physics simulator to ensure the laws of physics are abided by and the inverse dynamics network to predict motion. These are used in tandem to interpolate between consecutive keyframes from the downsampled motions generated by the deep generative model. The physics engine can receive the keyframes and produce a motion sequence of the original length of the captured motion data and the sample rate.

Block 206 includes generating motion in the inverse dynamics network to minimize the error between the physics simulator predicted next state and the true next state.

Block 208 includes using the physics simulator and the inverse dynamics network together to form the physics engine that includes the details in the downsampled deep generative model output. The training of the inverse dynamics network is decoupled from the training of the deep generative model, but the inverse dynamics network can be seamlessly incorporated with the deep generative model to produce detailed and physically reasonable motions at the test/inference time.

Block 210 includes generating a simulated motion video from the generated motion. The simulated motion video can be of any duration, including several seconds to several hours. Post processing operations can be applied to the simulated motion video such as smoothing or simulated audio corresponding to the simulated motion.

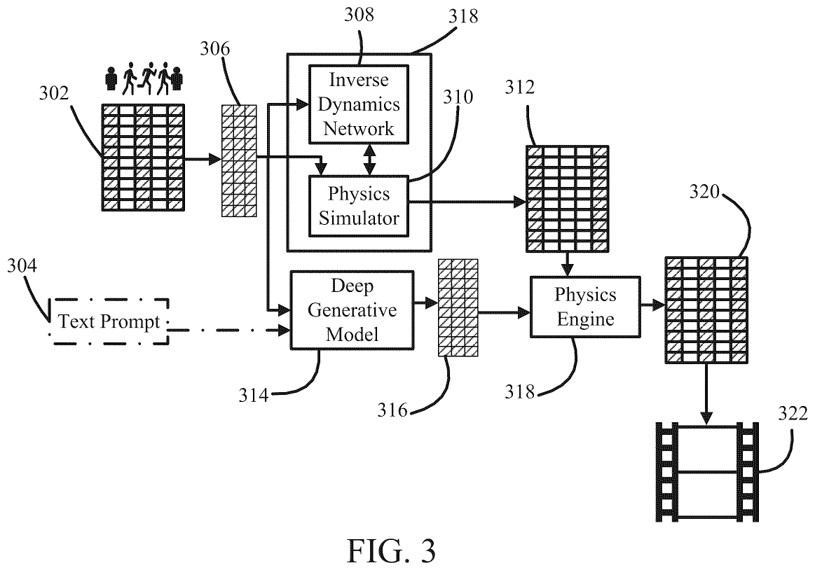

Now referring to FIG. 3, a flow diagram demonstrating the process of downsampling and interpolating motion generation is demonstrated. Motion generation can be defined as a sequence of generated motion denoted as x∈ [symbol] given an arbitrary condition c, where H is the number of time frames with regular time interval Δt, and M is the dimension of the motion representation.

Deep generative models 314 can learn the conditional distribution p(x|c) and generate new motions by sampling from a learned distribution. Text prompt 304 can be used to initiate deep generative model 314. The generative model 314 can use a convolutional neural network (CNN) or natural language processing (NPL) or other techniques to learn and process text prompt 304. The text prompt 304 can describe the original motion that is represented in original motion table 302. In other embodiments, the deep generative model can be initiated by other sources such images, audio, video, code, files, selections from a dropdown menu, checkboxes, sliders, physical gestures, and sensor data.

Ground truth motions are hereinafter denoted as x and generated motions are hereinafter denoted as \hat{x}. Sensor data can be collected for ground truth motions x over a given time and be represented by data in original motion table 302. Original motion table 302 represents data related to motion such as velocity, position, and angle over a given time. In some embodiments, the table can include data collected from gyroscopes, accelerometers, level sensors, position sensors, and image and video capture devices. Other sensors are also contemplated.

In an example, original motion table 302 may include data for motion starting as, e.g., a stationary person. The person then begins to gain walk and speed, eventually going from a standing position to a running position. After reaching the running position, the person can then transition back to the standing position. The columns of original motion table 302 represent increments of time and the rows of original motion table 302 represent different motion data. For example, one row can be for left leg position, while another is for left leg velocity, etc.

To generate a motion sequence \hat{x}∈ [symbol] with H frames and interval Δt, first the deep generative model 314 can be trained on a downsampled motion dataset. The dataset is downsampled such that all the motions in the dataset have a stride h, resulting in H/h keyframes with time interval hΔt. The value H/h can be selected to be an integer. After training, the generated output can be \hat{x}_{::h}∈ [symbol] . Downsample table 306 represents keyframes specifically selected for training the deep generative model 314 and other components.

For each original trajectory x_{1:H} (represented as time increments of original motion table 302), there can be multiple downsampled trajectories by starting at different frames and taking h through the end, e.g. x_{i:H:h} where i∈[1, h].

The trained inverse dynamics network 308 and the physics simulator 310 form a physics engine 318, which can receive frames xₜ and xₜ₊ₕ with time interval hΔt and output the combined motion \hat{x}_{t:t+h-1}. The physics engine 318 receives the data represented in downsample table 306 and feeds the data into the inverse dynamics network 308 and physics simulator 310 separately and simultaneously. Physics simulator 310 applies the laws of physics on the data represented in downsample table 306 and the predicted motion from inverse dynamics network 308 to output a physically possible generated motion. The physics simulator 310 verifies the predicted motion from the inverse dynamics network 308 and if the motion is impossible, informs the inverse dynamics network 308 that a new generated motion should be computed. The inverse dynamics network 308 outputs data into the physics simulator 310 and the physics simulator 310 outputs data into the inverse dynamics network 308. The inverse dynamics network 308 uses the data to predict the motion in the next timestep.

For example, the data represented in downsample table 306 may indicate a wall being kicked. The inverse dynamics network 308 may initially produce an output with the kick going through the wall as if the wall does not exist. The physics simulator 310 can indicate that the motion needs to be recomputed based on either the energy lost breaking the wall or reject the concept that the kick can go through the wall if the wall has material properties that make kicking through the wall impossible. In either instance the physics simulator 310 informs the inverse dynamics network 308 of the laws of physics.

The physics simulator 310 can receive the keyframes table 316 from the generative model 314 to interpolate between the downsampled keyframes. The result from physics engine 318 after receiving the downsampled table 306 is intermediary table 312. In some embodiments, intermediary table 312 is only temporary in forming generated motion. The data represented in intermediary table 312 is combined with the data represented in keyframes table 316 from the deep generative model 314 to produce data represented in generated motion table 320. The data in generated motion table 320 can correspond to the combined generated motion dataset \hat{x}_{1:H}.

The physics simulator 310 (denoted as Sim) receives the current state xₜ and an action aₜ as inputs and computes the state xₜ₊₁ at the next time frame according to its built-in physical laws. The state xₜ can include the position, rotation, velocity, acceleration, angular momentum, angular velocity, and other physical concepts of each joint in the structure. In other embodiments, more physical concepts may be included.

The action aₜ specifies the internal forces from the structure, which reflects the active movement. These elements are needed to simulate movement based on laws of motion. To simulate the movements numerically, actions aₜ, which refer to the forces or torques applied by the structure to actively control motion, could be obtained. Thus, for two adjacent input frames xₜ and xₜ₊ₕ, an inverse dynamics network 308 is trained to output the action in between, i.e. aₜ, and simulate the system by h steps with the physics simulator 310: \hat{x}ₜ₊ᵢ=Sim(\hat{x}ₜ₊₁₋₁, aₜ) for i=1, 2, . . . , h and \hat{x}ₜ:=xₜ. The inverse dynamics network 308 takes the initial and final states, represented in generalized coordinates and velocities, as input and outputs the joint forces during the hΔt time interval between the two states.

The inverse dynamics network 308 can be trained on the original dataset within original motion table 302. For every trajectory x_{1:H}, pairs of adjacent time frames are created (xₜ, xₜ₊ₕ) for t=1, 2, . . . , H−h. The inverse dynamics network 308 can produce the action aₜ that minimizes the difference between the simulator output \hat{x}ₜ₊ₕ and the ground truth final state xₜ₊ₕ, i.e. L=∥\hat{x}ₜ₊ᵢ−xₜ₊₁∥². The training of inverse dynamics network 308 can be completely decoupled from the deep generation model 314, so the inverse dynamics network 308 can be applied to different deep generative models 314 without having to retrain the inverse dynamics network 308, i.e., the models are agnostic from one another.

The combined motion for generated motion dataset \hat{x} is represented in generated motion table 320. During the sampling phase, the physics engine 318 can be applied to each pair of adjacent frames in the downsampled output of the generative model 314 and produce the full motion \hat{x}_{1:H} which conforms to the laws of physics. The generated motion table 320 can be used to generate simulated video 322. The simulated video 322 can be any be of any duration. The simulated video 322 incorporated the accuracy provided by physics engine 318 and the transitions between keyframes provided by deep generative model 314. The simulated video 322 can be WMV, MP4, WebM, MKV, AVCHD, MPEG-2, SWF, HEVC, M4V, FLY, F4V, VOB, DRC, GIF, MOV. Other video formats are also contemplated.

The simulated video 322 can be used in a variety of circumstances. For example, simulated video 322 can be used to train autonomous vehicles. Capturing motion for autonomous vehicle training is a lengthy and costly process. Reducing the amount of time and cost of training autonomous vehicles by simulating much of the motion would be advantageous. New motion can also be generated by inserting keyframes not from the original dataset. This would allow the autonomous vehicle to learn scenarios that it would not otherwise be able to train in a temporally and economically effective manner. Another example may be in the healthcare industry. Generating motion may show doctors how a prosthetic limb would be used and act in the fitting and research and development (R&D) phase. The advantages are similar to those of training an autonomous vehicle. In yet another example, simulated video 322 can be used in video games. In video games emulating human motion can be important to look realistic and add value to the user experience. For instance, in a soccer based video game, using simulated video 322 to acquire generated motion of an iconic scoring celebration would add significant value to the user experience. Also, generating motion of soccer ball trajectories may be improved and may reduce computation for generating motion. Other examples that generated motion may be used are computational fluid dynamics, computer aided design, computer aided engineering, computer aided machining, and manufacturing processes.

Further detailing the motion, motion can be represented by the generalized coordinates and velocities. Each pose can be quantified as x=(rₚ, r_{q}, jᵣ, rᵥ, rₐ, jₐ)∈ [symbol] . Ground truth motion x includes a root position rₚ∈ [symbol] , root rotation in quaternion r_{q}∈ [symbol] , root linear velocity and angular velocity rᵥ, rₐ∈ [symbol] , and joint angles and angular velocities jᵣ, j_{al ∈} [symbol] _{where D is the sum of degrees of freedom of J joints. This representation provides full information about the state of motion and can be used with the physics simulator 310.}

For a given motion representation xₜ including generalized coordinates and velocities, forward kinematics (FK) can be used to convert the motion into maximal coordinates for use in physics simulator 310 such that sₜ=FK(xₜ), which includes the position, rotation, linear velocity and angular velocity of each joint. The motion generation simulation can be performed based on the maximal coordinates, i.e. sₜ₊ᵢ=Sim(sₜ₊ᵢ₋₁, aₜ) in physics simulator 310. The loss for the inverse dynamics network 308 can also be computed with the maximal coordinates, i.e., L=∥sₜ₊ₕ−FK(xₜ₊ᵢ)∥². The output motion is obtained by applying inverse kinematics (IK) to each simulated frame, i.e. \hat{x}ₜ₊ᵢ=IK(sₜ₊ᵢ).

The motion can be combined from the physics engine 318 and deep generative model 314 in a variety of ways. In an embodiment, the motion can be combined to form generated motion table 320 by having the deep generative model 314 interpolate motion between keyframes and having the physics engine 318 verify the motion. In some embodiments there may be a threshold for accuracy of the generated motion. For example, if the generated motion is for a ball dropping on Earth. The ball may accelerate at 10 m/s instead of 9.81 m/s without triggering a mechanism to regenerate motion because the acceleration is within a predetermined threshold.

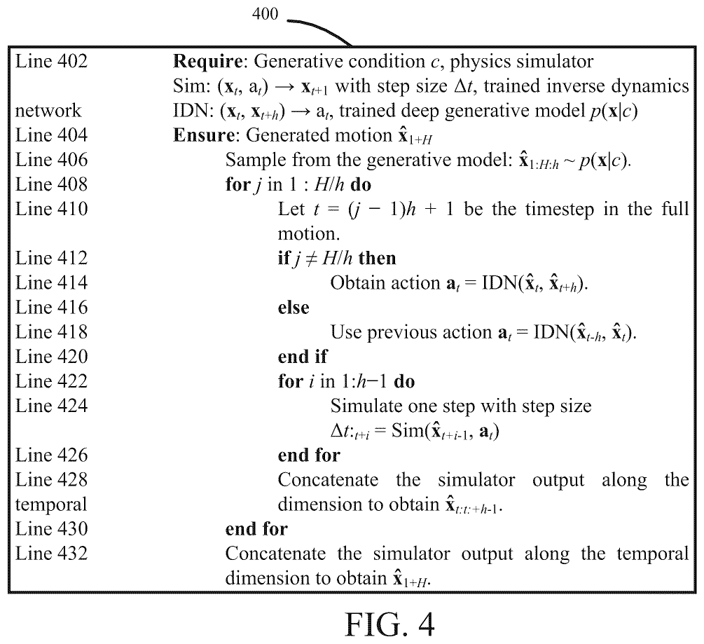

Now referring to FIG. 4, an algorithm 400 of the pipeline demonstrated in FIG. 3 is shown. Algorithm 400 is Python-pseudocode for the generation procedure. In embodiments, other programming languages can be used to implement the generation. Line 402 includes inputs for the algorithm 400 including the generative condition c for the probability p(x|c), the trained deep generative model 414, the physics simulator 310 (which outputs motion generation xₜ₊₁ from the motion xₜ and action aₜ for each time step Δt), and the inverse dynamics network 308 (which outputs action aₜ from xₜ and xₜ₊ₕ).

Line 404 includes the output generated motion \hat{x}ₜ₊ₓ. Line 406 is a sample from the deep generative model 314 according to \hat{x}_{i:x:h}˜p(x|c). Line 408 begins a loop which iterates H/h times, where H/h is an integer. The loop that is initiated on line 408 executes H/h times for line 410 to line 428. Line 410 defines variable t as (j−1)×h+1, where j is each iteration of the loop defined in line 408. The variable t is the timestep of the motion generation. Line 412 is a conditional statement such that if j is not H/h, then obtain action aₜ=IDN(\hat{x}ₜ, \hat{x}ₜ₊ₕ). IDN calls a function acting as the inverse dynamics network 308. In other words, if the iteration is not on the last iteration, use the inverse dynamics network 308 to predict the next motion. In line 416 the alternative to the condition in line 412 is stated. If j is H/h then, according to line 418, use the previous iteration action aₜ=IDN(\hat{x}ₜ₋ₕ, \hat{x}ₜ). Line 420 ends the conditional in line 412 to line 420.

Line 422 is a nested loop. The number of iterations is defined as h−1. Accordingly, line 424 states that the physics simulator 310 should predict the motion. The timestep is defined as Δt:ₜ₊ᵢ=Sim(\hat{x}ₜ₊ᵢ₋₁, aₜ). Line 426 ends the inner loop. Line 428 concatenates the physics simulator 310 output along the temporal dimension to obtain \hat{x}_{t:t:+h-1}. Line 430 ends the outer loop. Line 432 concatenates the physics simulator 310 output along the temporal dimension to obtain \hat{x}_{1+H}.

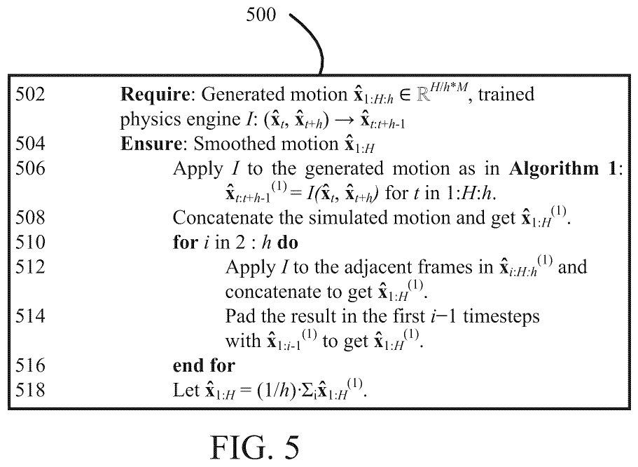

Now referring to FIG. 5, a method for smoothing the generated motion. Once the motion is generated, the motion may appear disjointed. The generated motion can be smoothed in a post-processing technique to appear more natural and realistic. Algorithm 500 incorporates algorithm 400 to smooth the generated motion according to some embodiments. The smoothing smooths the concatenated output produces continuous motions.

After generating motion (e.g., algorithm 400), the different downsampled trajectories of the simulation can be used, starting from different timesteps, to perform physics-based interpolation. Then, there are h different simulated trajectories, each covering different initial and final states. Finally, the smoothed motion is obtained by averaging over these trajectories, which has a similar effect to a sliding window over h frames and eliminates the discontinuity in the physics-based interpolation. Starting at different timesteps can allow for slightly different trajectories. These different trajectories are then averaged for a smooth motion.

Algorithm 500 is Python-pseudocode for the smoothing. In embodiments, other programming languages can be used to implement the smoothing. Line 502 defines the inputs as generated motion \hat{x}_{1:H:h}∈ [symbol] and trained physics engine 318 which receives input (\hat{x}ₜ, \hat{x}ₜ₊ₕ) and outputs \hat{x}_{t:t+h-1}. Line 504 states that the output is a smooth motion \hat{x}_{1:H}. Line 506 applies the physics engine 318 by calling algorithm 400. In some embodiments the physics engine 318 could involve other procedures. The smoothing function and the physics engine 318 are agnostic to one another. Furthermore, in other embodiments the physics engine 318 can be incorporated into the smoothing function or the smoothing function can be incorporated into the physics engine 318. The physics engine 318 can be described as \hat{x}_{t:t+h-1}⁽¹⁾=I(\hat{x}ₜ, \hat{x}ₜ₊ₕ) for t in 1:H:h. Line 508 concatenates the simulated generated motion to form \hat{x}_{1:H}⁽¹⁾.

Line 510 is a loop starting at index 2 and iterating until h. In other words, first frame can remain the same and the function only applies processing of the keyframes starting at the index 2. Line 512 calls a function to execute the physics engine 318 to the frames adjacent to \hat{x}_{i:H:h}⁽¹⁾. The simulated motion is then concatenated to form \hat{x}_{1:H}⁽¹⁾. Line 514 pads the results from line 512 with \hat{x}_{1:i-1}⁽¹⁾ to get \hat{x}_{1:H}⁽¹⁾. Line 516 ends the loop. Line 518 sets variable \hat{x}_{1:H} as

$$\frac{1}{h} {\sum }_{i} {{\hat{x}}_{1 : H}}^{( 1 )} . \qquad ( 1 )$$

The smoothness of the generated motion can be defined by a metric upon which the quality of the smoothing process can be quantified. The metric is defined as the average magnitude of accelerations across all time frames and joints in the generated motions, i.e.

$${𝔼}_{x} [ \frac{1}{b} {\sum }_{t = 1}^{H - 1} {‖ {( {j}_{a} )}_{t + 1} - {( {j}_{a} )}_{t} ‖}^{2} ] ,$$

where b=(H−1)×D, where x is the generated motion, jₐ denotes the component of joint angular velocities and D is the dimensionality of jₐ. This metric is closely related to the output of the inverse dynamics network 308.

The metric can be denoted as a smoothness action as the metric refers to all the action for a structure to perform a given motion. Smoothness action is measured in the observable space to better align with visual effects than unobservable physical quantities, forces, and torques can. The smoothness action would be 0 if the motion is uniform. A significant amount of motion would lead to a high smoothness action value.

Applying physics engine 318 to motion datasets often raises the smoothness action value of the generated motion dataset. Conversely, applying smoothing algorithms like algorithm 500 often decreases the smoothness action value on generated motion datasets. Smoothing algorithm 500 further brings the generated motion closer to the ground truth motion.

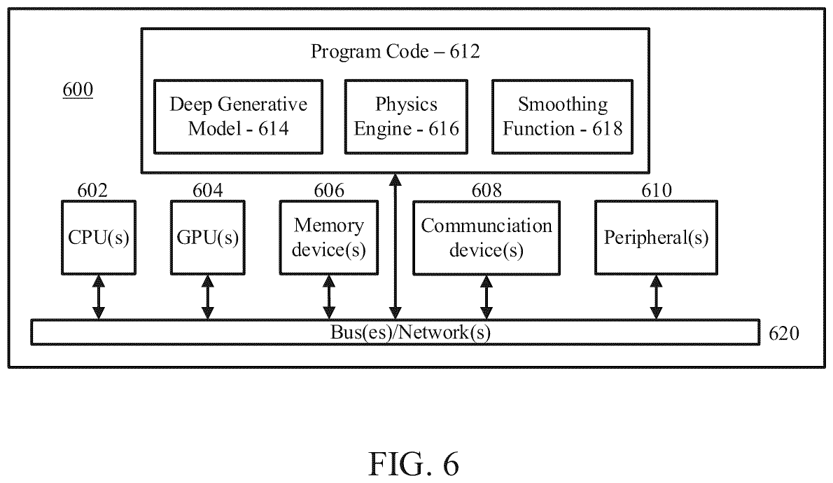

FIG. 6 is a block diagram showing an exemplary processing system 600, in accordance with an embodiment of the present invention. The processing system 600 includes a set of processing units (e.g., CPUs) 602, a set of GPUs 604, a set of memory devices 606, a set of communication devices 608, and a set of peripherals 610. The CPUs 602 can be single or multi-core CPUs. The GPUs 604 can be single or multi-core GPUs. The one or more memory devices 606 can include caches, RAMs, ROMs, and other memories (flash, optical, magnetic, etc.). The communication devices 608 can include wireless and/or wired communication devices (e.g., network (e.g., WIFI, etc.) adapters, etc.). The peripherals 610 can include a display device, a user input device, a printer, an imaging device, and so forth. Elements of processing system 600 are connected by one or more buses or networks (collectively denoted by the figure reference numeral 620).

In an embodiment, memory devices 606 can store specially programmed software modules to transform the computer processing system into a special purpose computer configured to implement various aspects of the present invention. In an embodiment, special purpose hardware (e.g., Application Specific Integrated Circuits, Field Programmable Gate Arrays (FPGAs), and so forth) can be used to implement various aspects of the present invention.

In an embodiment, memory devices 606 store program code 612 for implementing one or more of the following functions: generating motion with the deep generative model 614, generating motion with the physic engine 616, and smoothing function for smoothing the generated motion 618.

Of course, the processing system 600 may also include other elements (not shown), as readily contemplated by one of skill in the art, as well as omit certain elements. For example, various other input devices and/or output devices can be included in processing system 600, depending upon the particular implementation of the same, as readily understood by one of ordinary skill in the art. For example, various types of wireless and/or wired input and/or output devices can be used. Moreover, additional processors, controllers, memories, and so forth, in various configurations can also be utilized. These and other variations of the processing system 600 are readily contemplated by one of ordinary skill in the art given the teachings of the present invention provided herein.

Moreover, the various figures as described below with respect to various elements and steps relating to the present invention that may be implemented, in whole or in part, by one or more of the elements of system 600.

Embodiments described herein may be entirely hardware, entirely software or including both hardware and software elements. In a preferred embodiment, the present invention is implemented in software, which includes but is not limited to firmware, resident software, microcode, etc.

Embodiments may include a computer program product accessible from a computer-usable or computer-readable medium providing program code for use by or in connection with a computer or any instruction execution system. A computer-usable or computer readable medium may include any apparatus that stores, communicates, propagates, or transports the program for use by or in connection with the instruction execution system, apparatus, or device. The medium can be magnetic, optical, electronic, electromagnetic, infrared, or semiconductor system (or apparatus or device) or a propagation medium. The medium may include a computer-readable storage medium such as a semiconductor or solid state memory, magnetic tape, a removable computer diskette, a random access memory (RAM), a read-only memory (ROM), a rigid magnetic disk and an optical disk, etc.

Each computer program may be tangibly stored in a machine-readable storage media or device (e.g., program memory or magnetic disk) readable by a general or special purpose programmable computer, for configuring and controlling operation of a computer when the storage media or device is read by the computer to perform the procedures described herein. The inventive system may also be considered to be embodied in a computer-readable storage medium, configured with a computer program, where the storage medium so configured causes a computer to operate in a specific and predefined manner to perform the functions described herein.

A data processing system suitable for storing and/or executing program code may include at least one processor coupled directly or indirectly to memory elements through a system bus. The memory elements can include local memory employed during actual execution of the program code, bulk storage, and cache memories which provide temporary storage of at least some program code to reduce the number of times code is retrieved from bulk storage during execution. Input/output or I/O devices (including but not limited to keyboards, displays, pointing devices, etc.) may be coupled to the system either directly or through intervening I/O controllers.

Network adapters may also be coupled to the system to enable the data processing system to become coupled to other data processing systems or remote printers or storage devices through intervening private or public networks. Modems, cable modem and Ethernet cards are just a few of the currently available types of network adapters.

As employed herein, the term “hardware processor subsystem” or “hardware processor” can refer to a processor, memory, software or combinations thereof that cooperate to perform one or more specific tasks. In useful embodiments, the hardware processor subsystem can include one or more data processing elements (e.g., logic circuits, processing circuits, instruction execution devices, etc.). The one or more data processing elements can be included in a central processing unit, a graphics processing unit, and/or a separate processor- or computing element-based controller (e.g., logic gates, etc.). The hardware processor subsystem can include one or more on board memories (e.g., caches, dedicated memory arrays, read only memory, etc.). In some embodiments, the hardware processor subsystem can include one or more memories that can be on or off board or that can be dedicated for use by the hardware processor subsystem (e.g., ROM, RAM, basic input/output system (BIOS), etc.).

In some embodiments, the hardware processor subsystem can include and execute one or more software elements. The one or more software elements can include an operating system and/or one or more applications and/or specific code to achieve a specified result.

In other embodiments, the hardware processor subsystem can include dedicated, specialized circuitry that performs one or more electronic processing functions to achieve a specified result. Such circuitry can include one or more application-specific integrated circuits (ASICs), field-programmable gate arrays (FPGAs), and/or programmable logic arrays (PLAs).

These and other variations of a hardware processor subsystem are also contemplated in accordance with embodiments of the present invention.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment,” as well any other variations, appearing in various places throughout the specification are not necessarily all referring to the same embodiment. However, one or more embodiments can be combined given the teachings of the present invention provided herein.

Use of any of the following “I”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended for as many items listed.

The foregoing is to be understood as being in every respect illustrative and exemplary, but not restrictive, and the scope of the invention disclosed herein is not to be determined from the Detailed Description, but rather from the claims as interpreted according to the full breadth permitted by the patent laws. The embodiments shown and described herein are only illustrative of the present invention and that those skilled in the art may implement various modifications without departing from the scope and spirit of the invention. Those skilled in the art could implement various other feature combinations without departing from the scope and spirit of the invention. Having thus described aspects of the invention, with the details and particularity required by the patent laws, what is claimed and desired protected by Letters Patent is set forth in the appended claims.

What is claimed is:

1. A computer implemented method, comprising:
converting a motion dataset to a compatible representation for use in a physics engine, wherein the physics engine includes a physics simulator and inverse dynamics network;
downsampling the motion dataset to obtain keyframes for motion generation and forming a downsampled motion dataset;
executing a deep generative model based on the downsampled motion dataset to generate a first generated motion;
executing the physics engine by feeding pairs of consecutive keyframes into the physics simulator and the inverse dynamics network to generate a second generated motion;
combining the first generated motion and the second generated motion to form a combined generated motion, wherein the combined generated motion is generated by executing the physics engine; and
generating a simulated motion video from the combined generated motion.

2. The computer implemented method of claim 1, wherein, the keyframes in the downsampled motion dataset includes a set of poses of maximal coordinates of joints of a structure.

3. The computer implemented method of claim 1, wherein, the physics engine generates an intermediary simulated motion from the downsampled motion dataset.

4. The computer implemented method of claim 1, further comprising;
smoothing the combined generated motion, the smoothing including;
performing motion generation, starting at different timesteps corresponding with different keyframes to obtain different generated motion trajectories; and
averaging different combined generated motion trajectories corresponding to different timesteps.

5. The computer implemented method of claim 1, wherein the motion dataset includes motion data collected from sensors.

6. The computer implemented method of claim 1, wherein the physics simulator outputs data into the inverse dynamics network and the inverse dynamics network outputs data into the physics simulator.

7. The computer implemented method of claim 1, wherein the inverse dynamics network forms a path between a current keyframe to a next keyframe considering joint forces, torques, and acceleration.

8. A system, comprising:
a hardware processor; and
a memory that stores a computer program which, when executed by the hardware processor, causes the hardware processor to:
convert a motion dataset to a compatible representation; for use in a physics engine, wherein the physics engine includes a physics simulator and inverse dynamics network;
downsample the motion dataset to obtain keyframes for motion generation and forming a downsampled motion dataset;
execute a deep generative model based on the downsampled motion dataset to generate a first generated motion;
execute the physics engine by feeding pairs of consecutive keyframes into the physics simulator and the inverse dynamics network to generate a second generated motion;
combine the first generated motion and the second generated motion to form a combined generated motion, wherein the combined generated motion is generated by executing the physics engine; and
generate a simulated motion video from the combined generated motion.

9. The system of claim 8, wherein, the keyframes in the downsampled motion dataset includes a set of poses of maximal coordinates of joints of a structure.

10. The system of claim 8, wherein, the physics engine generates an intermediary simulated motion from the downsampled motion dataset.

11. The system of claim 8, further comprising;
the memory causes the hardware processor to smooth the combined generated motion, the combined generated motion is smoothed by causing the hardware processor;
perform motion generation, starting at different timesteps corresponding with different keyframes to obtain different generated motion trajectories; and
average different combined generated motion trajectories corresponding to different timesteps.

12. The system of claim 8, wherein the motion dataset includes motion data collected from sensors.

13. The system of claim 8, wherein the physics simulator outputs data into the inverse dynamics network and the inverse dynamics network outputs data into the physics simulator.

14. The system of claim 8, wherein the inverse dynamics network forms a path between a current keyframe to a next keyframe considering body joint forces, torques, and acceleration.

15. A computer program product comprising a non-transitory computer-readable storage medium containing computer program code, the computer program code when executed by one or more processors causes the one or more processors to perform operations, the computer program code comprising instructions to:
convert a motion dataset to a compatible representation; for use in a physics engine, wherein the physics engine includes a physics simulator and inverse dynamics network;
downsample the motion dataset to obtain keyframes for motion generation and forming a downsampled motion dataset;
execute a deep generative model based on the downsampled motion dataset to generate a first generated motion;
execute the physics engine by feeding pairs of consecutive keyframes into the physics simulator and the inverse dynamics network to generate a second generated motion;
combine the first generated motion and the second generated motion to form a combined generated motion, wherein the combined generated motion is generated by executing the physics engine; and
generate a simulated motion video from the combined generated motion.

16. The computer program product of claim 15, wherein, the keyframes in the downsampled motion dataset includes a set of poses of maximal coordinates of joints of a structure.

17. The computer program product of claim 15, wherein, the physics engine generates an intermediary simulated motion from the downsampled motion dataset.

18. The computer program product of claim 15, the computer program code further comprising instructions to;
perform motion generation, starting at different timesteps corresponding with different keyframes to obtain different generated motion trajectories; and
average different combined generated motion trajectories corresponding to different timesteps.

19. The computer program product of claim 15, wherein the physics simulator outputs data into the inverse dynamics network and the inverse dynamics network outputs data into the physics simulator.

20. The computer program product of claim 15, wherein the inverse dynamics network forms a path between a current keyframe to a next keyframe considering body joint forces, torques, and acceleration.
